(19) United States
(12) Patent Application Publication
(10) Pub. No.: US 2024/0004583 A1
(43) Pub. Date: Jan. 4, 2024

(54) PROTOCOL FOR DATA POISONING

(71) Applicants: Advanced Micro Devices, Inc., Santa Clara, CA (US); ATI Technologies ULC, Markham (CA)

(72) Inventors: Aaron John Nygren, Boise, ID (US); Michael John Litt, Toronto (CA)

(73) Assignees: Advanced Micro Devices, Inc., Santa Clara, CA (US); ATI Technologies ULC, Markham (CA)

(21) Appl. No.: 17/854,953

(22) Filed: Jun. 30, 2022

(51) Int. Cl. G06F 3/06

(52) U.S. Cl. CPC G06F 3/0659; G06F 3/0619; G06F 3/0673

(57) ABSTRACT

A random-access memory (RAM) includes a plurality of memory banks, a memory channel interface circuit, and a metadata processing circuit. The memory channel interface circuit couples to a memory channel adapted for coupling to a memory controller. The metadata processing circuit is connected to the memory channel interface circuit and receiving a poison bit sent over the memory channel associated with a write command and write data for the write command. The RAM, responsive to the poison bit indicating that the write data is poisoned, stores at least one of: the poison bit and a code indicating a value of the poison bit in a selected memory bank.

### BACKGROUND

Computer systems typically use inexpensive and high density dynamic random access memory (DRAM) chips for main memory. Most DRAM chips sold today are compatible with various double data rate (DDR) DRAM standards promulgated by the Joint Electron Devices Engineering Council (JEDEC). DDR DRAMs use conventional DRAM memory cell arrays with high-speed access circuits to achieve high transfer rates and to improve the utilization of the memory bus.

In modern servers, such as cloud data center servers, the server crash rate is an important metric for managing a data center. To reduce and mitigate server crashes, reliability, availability, and serviceability (RAS) systems are included in server data processors. Modern RAS systems often include a machine-check architecture (MCA) for tracking and handling hardware errors and failures of various kinds in order to mitigate and recover from crashes. Data poisoning is a feature of such RAS systems which allows, processor, a cache system, a memory system, or other processing element to indicate to the host operating system that a particular line of data includes an unrecoverable error.

### BRIEF DESCRIPTION OF THE DRAWINGS

FIG. 1 illustrates in block diagram form a portion of a memory system according to the prior art;

FIG. 2 illustrates in block diagram for a data processing system according to some embodiments;

FIG. 3 illustrates in block diagram form a portion of a data processing system including high-speed dynamic random-access memory (DRAM) according to some embodiments;

FIG. 4 illustrates in block diagram form a portion of a memory system according to some embodiments;

FIG. 5 illustrates in diagram form a set of data stored in a memory according to some embodiments;

FIG. 6 illustrates in diagram form a set of data stored in a memory according to some other embodiments;

FIG. 7 is a flow diagram of a process for performing storing data poison information according to some embodiments; and

FIG. 8 is a flow diagram of a process for reading data from a DRAM memory including a poison indication according to some embodiments.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

A random-access memory (RAM) includes a plurality of memory banks, a memory channel interface circuit, and a metadata processing circuit. The memory channel interface circuit couples to a memory channel adapted for coupling to a memory controller. The metadata processing circuit is connected to the memory channel interface circuit and receiving a poison bit sent over the memory channel associated with a write command and write data for the write command. The RAM, responsive to the poison bit indicating that the write data is poisoned, stores at least one of: the poison bit and a code indicating a value of the poison bit in a selected memory bank.

A method includes, at a random-access memory (RAM), receiving a poison bit sent over a memory channel associated with a write command and write data for the write command. At the RAM, responsive to the poison bit indicating that the write data is poisoned, the method includes storing at least one of: the poison bit and a code indicating a value of the poison bit in a selected memory bank of the RAM. Responsive to a read command for the write data, the method includes transmitting the poison bit to a memory controller.

A data processing system includes a data processor, a data fabric coupled to the data processor, a memory controller coupled to the data fabric for fulfilling memory requests from the data processor, and a random access memory (RAM) coupled to the memory controller over a memory channel. The RAM includes a plurality of memory banks, a memory channel interface circuit for coupling to a memory channel adapted for coupling to a memory controller, and a metadata processing circuit coupled to the memory channel interface circuit. The metadata processing circuit receives a poison bit sent over the memory channel associated with a write command and write data for the write command. The RAM, responsive to the poison bit indicating that the write data is poisoned, stores at least one of: the poison bit and a code indicating a value of the poison bit in a selected memory bank

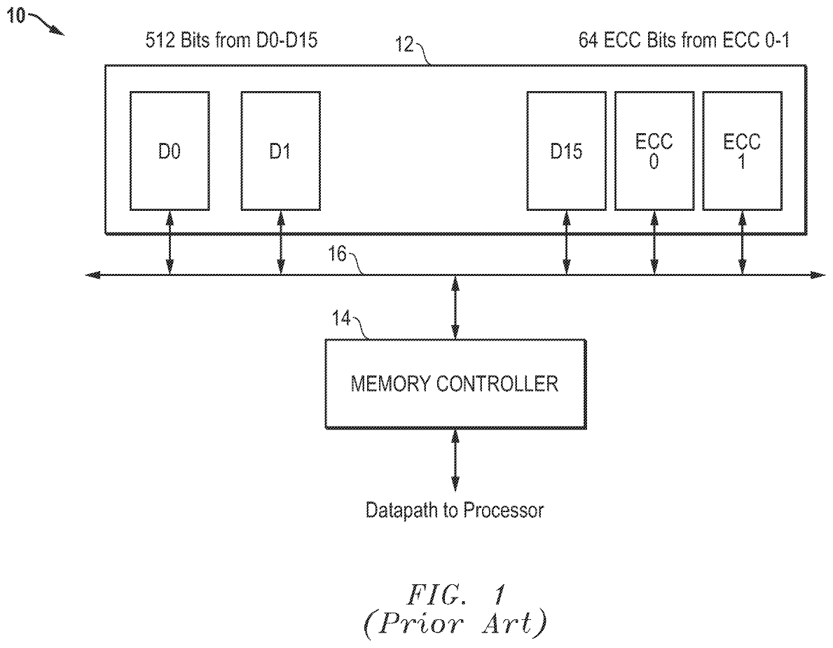

FIG. 1 illustrates in block diagram form a portion of a memory system 10 according to the prior art. Memory system 10 includes a memory module 12 and a memory controller 14 connected to memory module 12 over a memory bus 16. Memory module 12 includes a plurality of DRAM chips labelled “D0”-“D15” and “ECC0”-“ECC1”. In the depicted arrangement, typical for GDDR DRAM memory modules, DRAM chips D0-D15 hold data written to memory, while DRAM chips ECC0-ECC1 hold error correction code (ECC) data associated with data stored in DRAM chips D0-D15. As shown, for each 512 bits stored in DRAM chips D0-D15, 64 bits of ECC are held in DRAM chips ECC0-ECC1.

In operation, memory controller 14 produces the ECC bits and writes them to memory module 12 along with corresponding data. When the data is read from memory module 12, the ECC data is also read, and memory controller 14 checks the ECC to detect errors.

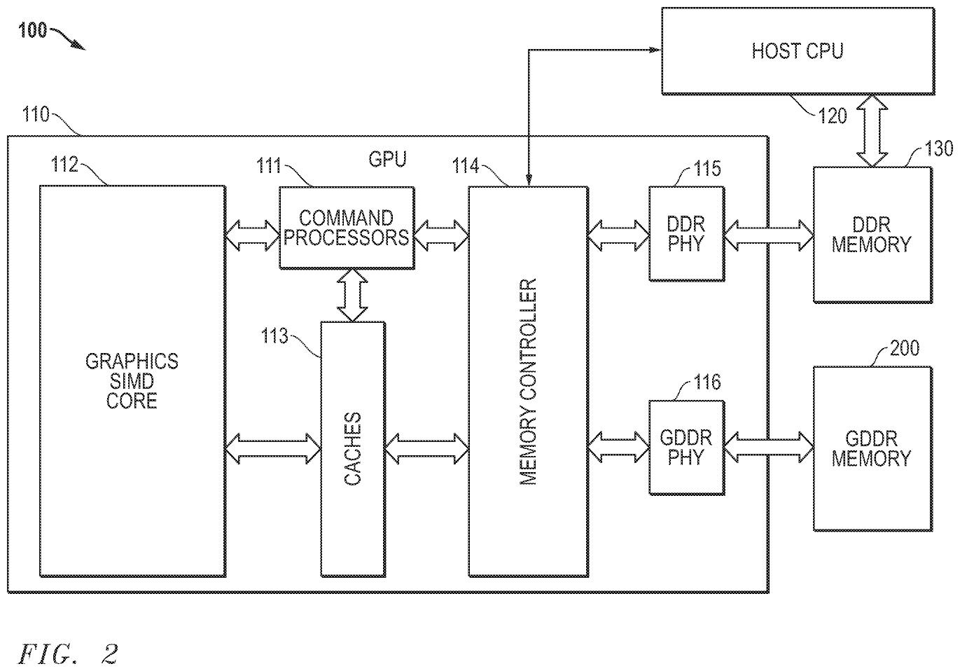

FIG. 2 illustrates in block diagram for a data processing system 100 according to some embodiments. Data processing system 100 includes generally a data processor in the form of a graphics processing unit (GPU) 110, a host central processing unit (CPU) 120, a double data rate (DDR) memory 130, and a graphics DDR (GDDR) memory 140. While FIG. 2 shows a GPU, the techniques herein may be employed with GPUs or other computer processors which can benefit from tracking data poisoning on a DDR memory interface.

GPU 110 is a discrete graphics processor that has extremely high performance for optimized graphics processing, rendering, and display, but requires a high memory bandwidth for performing these tasks. GPU 110 includes generally a set of command processors 111, a graphics single instruction, multiple data (SIMD) core 112, a set of caches 113, a memory controller 114, a DDR physical interface circuit (PHY) 115, and a GDDR PHY 116.

Command processors 111 are used to interpret high-level graphics instructions such as those specified in the OpenGL programming language. Command processors 111 have a bidirectional connection to memory controller 114 for receiving the high-level graphics instructions, a bidirectional connection to caches 113, and a bidirectional connection to graphics SIMD core 112. In response to receiving the high-level instructions, command processors 111 issue SIMD instructions for rendering, geometric processing, shading, and rasterizing of data, such as frame data, using caches 113 as temporary storage. In response to the graphics instructions, graphics SIMD core 112 executes the low-level instructions on a large data set in a massively parallel fashion. Command processors 111 use caches 113 for temporary storage of input data and output (e.g., rendered and rasterized) data. Caches 113 also have a bidirectional connection to graphics SIMD core 112, and a bidirectional connection to memory controller 114.

Memory controller 114 has a first upstream port connected to command processors 111, a second upstream port connected to caches 113, a first downstream bidirectional port, and a second downstream bidirectional port. As used herein, “upstream” ports are on a side of a circuit toward a data processor and away from a memory, and “downstream” ports are on a side if the circuit away from the data processor and toward a memory. Memory controller 114 controls the timing and sequencing of data transfers to and from DDR memory 130 and GDDR memory 140. DDR and GDDR memory support asymmetric accesses, that is, accesses to open pages in the memory are faster than accesses to closed pages. Memory controller 114 stores memory access commands and processes them out-of-order for efficiency by, e.g., favoring accesses to open pages, disfavoring frequent bus turnarounds from write to read and vice versa, while observing certain quality-of-service objectives.

DDR PHY 115 has an upstream port connected to the first downstream port of memory controller 114, and a downstream port bidirectionally connected to DDR memory 130. DDR PHY 115 meets all specified timing parameters of the implemented version or versions of DDR memory 130, such as DDR version five (DDR5), and performs training operations at the direction of memory controller 114. Likewise, GDDR PHY 116 has an upstream port connected to the second downstream port of memory controller 114, and a downstream port bidirectionally connected to GDDR memory 200. GDDR PHY 116 meets all specified timing parameters of the implemented version of GDDR memory 140, and performs training operations at the direction of memory controller 114.

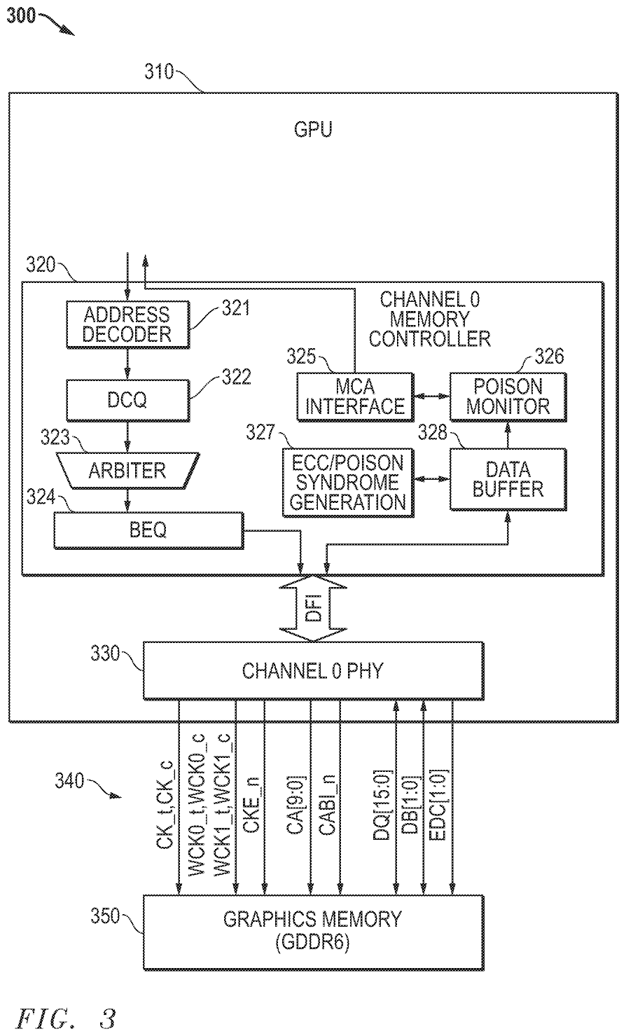

FIG. 3 illustrates in block diagram form a portion of a data processing system 300 including high-speed dynamic random-access memory (DRAM) according to some embodiments. Data processing system 300 includes generally a graphics processing unit 310 labelled “GPU”, a memory channel 340, and a DRAM 350 labelled “GRAPHICS MEMORY (GDDR)”.

Graphics processing unit 310 includes a memory controller 320 and a physical interface circuit 330 labelled “PHY”, as well as conventional components of a GPU that are not relevant to the training technique described herein and are not shown in FIG. 1. Memory controller 320 includes an address decoder 321, a command queue 322 labelled “DCQ”, an arbiter 323, a back-end queue 324 labelled “BEQ”, a machine-check architecture (MCA) interface circuit 325, a poison monitor circuit 326, a ECC/Poison syndrome generation circuit 327, and a data buffer 328. Other functional blocks may be included but are not shown to avoid obscuring the relevant features.

Address decoder 321 has an input for receiving addresses of memory access request received from a variety of processing engines in graphics processing unit 310 (not shown in FIG. 1), and an output for providing decoded addresses. Command queue 322 has an input connected to the output of command queue 322, and an output. Arbiter 323 has an input connected to command queue 322, and an output. Back-end queue 324 has a first input connected to the output of arbiter 323, a second input, a first output, and a second output not shown in FIG. 1 for providing memory commands to physical interface circuit 330. MCA interface circuit 325 has an output for reporting MCA errors to GPU 310, and a bidirectional connection to poison monitor circuit 326. Poison monitor circuit 326 also has an input connected to data buffer 328 for monitoring the poison bits of received data. ECC/Poison syndrome generation circuit 327 has a bidirectional connection to data buffer 328. Data buffer 328 also has a bidirectional connection to PHY 330 for sending and receiving data, an output connected to poison monitor 326, and various other connections not shown for controlling data buffer 328.

PHY 330 has an upstream port bidirectionally connected to memory controller 320 over a bus labeled “DFI”, and a downstream port. The DFI bus is compatible with the DDR-PHY Interface Specification that is published and updated from time-to-time by DDR-PHY Interface (DFI) Group.

Memory 350 is a memory especially suited for used with high-bandwidth graphics processors such as graphics processing unit 310. Memory 350 uses a physical interface signaling standard with a 16-bit data bus, optional data bus inversion (DBI) bits, error detection code bits, and separate differential read and write clocks in order to ensure high speed transmission per-pin bandwidth of up to 16 giga-bits per second (16 GB/s). The interface signals are shown in TABLE I below:

TABLE I

| Signal | Direction | |
|---|---|---|
| Name | from PHY | Description |
| CK_t, | Output | Clock: CK_t and CK_c are differential clock inputs. CK_t and CK_c do not have |
| CK_c | | channel indicators as one clock is shared between both Channel A and Channel B |
| | | on a device. Command Address (CA) inputs are latched on the rising and falling |
| | | edge of CK. All latencies are referenced to CK. |
| WCK0_t, | Output | Write Clocks: WCK_t and WCK_c are differential clocks used for WRITE data |
| WCK0_c, | | capture and READ data output. WCK0_t/WCK0_c is associated with DQ[7:0], |
| WCK1_t, | | DBI0_n and EDC0. WCK1_t/WCK1_c is associated with DQ[15:8], DBI1_n |
| WCK1_c | | and EDC1. |
| CKE_n | Output | Clock Enable: CKE_n LOW activates and CKE_n HIGH deactivates the internal |
| | | clock, device input buffers, and output drivers excluding RESET_n, TDI, TDO, |
| | | TMS and TCK. |
| CA[9:0] | Output | Command Address (CA) Outputs: The CA outputs provide packetized DDR |
| | | commands, address or other information, for example, the op-code for the MRS |
| | | command. |
| DQ[15:0] | I/O | Data Input/Output: 16-bit data bus |
| DBI[1:0]_n | I/O | I/O Data Bus Inversion. DBI0_n is associated with DQ[7:0], DBI1_n is |
| | | associated with DQ[15:8]. |
| EDC[1:0] | I/O | Error Detection Code. The calculated CRC data is transmitted on these signals. |
| | | In addition these signals drive a ‘hold’ pattern when idle. EDC0 is associated |
| | | with DQ[7:0], EDC1 is associated with DQ[15:8]. |
| CABI_n | Output | Command Address Bus Inversion |

In operation, memory controller 320 is a memory controller for a single channel, known as Channel 0, but GPU 310 may have other memory channel controllers not shown in FIG. 1. Memory controller 320 includes circuitry for grouping accesses and efficiently dispatching them to memory 350. Address decoder 321 receives memory access requests, and remaps the addresses relative to the address space of memory 350. Address decoder 321 may also optionally scramble or “hash” addresses in order to reduce the overhead of opening and closing pages in memory 350.

Command queue 322 stores the memory access requests including the decoded memory addresses as well as metadata such as quality of service requested, aging information, direction of the transfer (read or write), and the like.

Arbiter 323 selects memory accesses for dispatch to memory 350 according to a set of policies that ensure both high efficiency and fairness, for example, to ensure that a certain type of accesses does not hold the memory bus indefinitely. In particular, it groups accesses according to whether they can be sent to memory 350 with low overhead because they access a currently-open page, known as “page hits”, and accesses that require the currently open page in the selected bank of memory 350 to be closed and another page opened, known as “page conflicts”. By efficiently grouping accesses in this manner, arbiter 323 can partially hide the inefficiency caused by lengthy overhead cycles by interleaving page conflicts with page hits to other banks.

Back-end queue 324 gathers the memory accesses selected by arbiter 323 and sends them in order to memory 350 through physical interface circuit 330. It also multiplexes certain non-memory-access memory commands, such as mode register write cycles, refreshes, error recovery sequences, and training cycles with normal read and write accesses.

Physical interface circuit 330 includes circuitry to provide the selected memory access commands to memory 350 using proper timing relationships and signaling. In particular in GDDR6, each data lane is trained independently to determine the appropriate delays between the read or write clock signals and the data signals. The timing circuitry, such as delay locked loops, is included in physical interface circuit 330. Control of the timing registers, however, is performed by memory controller 320.

When write commands are received at memory controller 320, associated data is loaded to data buffer 328, and ECC/Poison syndrome generation circuit 327 determines whether the write command includes an indication that the data is poisoned. ECC/Poison syndrome generation circuit 327 generates the ECC code for the data, and may set a poison bit in the data or generate a poison syndrome or other code to indicate whether the data is poisoned. In other implementations, a poison syndrome may be generated on the DRAM, as further described below. The ECC and poison indication are sent over the PHY on the DQ lines to GDDR memory 140. Generally, the GDDR memory modules supports tracking data poisoning through its memory bus protocol. Prior DDR standards do not support tracking data poisoning status, that is, information indicating that particular memory data has been determined by the host system to be corrupted, within the communications protocol between the memory controller and the DRAM memory. Nor do prior DDR DRAM protocols include a designated location to store “poison” information.

When read commands are fulfilled by GDDR memory 140 and read data is received at data buffer 328, the poison indication is also sent as part of the data payload of the read command, as further described below. Poison monitor circuit 326 checks the received poison indication to determine if the data is poisoned. If so, poison monitor circuit 326 signals to MCA interface 325 that the received data is poisoned. MCA interface 325 then reports the poisoned state of the data to the machine-check architecture system of GPU 310.

FIG. 4 illustrates in block diagram form a portion of a memory system 400 according to some embodiments. The depicted memory system 400 includes a memory module 410 in communication with a memory controller 420 over a memory bus 415. Memory module 410 is suitable for use with system 300 of FIG. 3 and other similar GPU or accelerated processing unit (APU) systems. Memory module 410 includes a plurality of DRAM chips labelled “D0”-“D15”.

Each of DRAM chips D0-D15 hold data written to memory and are accessed with a wider interface, such as a 32-bit interface, than that employed with typical DDR memory chips, which are often accessed in a 4-wide or 8-wide configuration. Rather than using separate DRAM chips to hold ECC data, each DRAM chip has a respective region, labelled “ECC0”, “ECC1”-“ECC15” holding ECC data for the data stored in that respective DRAM chip. In the depicted implementation, each DRAM chip also includes a metadata processing circuit labelled “DECODE”, which includes digital logic used to encode and decode poison bit information for data written and read from the memory chip, as further described below. In other implementations, the metadata processing circuit may not perform encoding or decoding, but instead merely recognize the poison bit provided over the data interface and cause it to be stored in a respective dedicated bit in the DRAM memory for each respective row of memory in the DRAM chip.

On the right of the diagram is shown an expanded view of DRAM chip D15, along with its data buffer 414 labelled “DB”. Typically each data buffer 414 is a separate chip interfacing with at least one DRAM chip on memory module 414. Each DRAM chip is similarly constructed. DRAM chip D15 includes a number of physical banks labelled “BANK 0” through “BANK N−1”, which include a number of rows of DRAM storage bits. As depicted, each row includes DRAM bits labelled “DATA” for storing the data, and additional DRAM bits labelled “ECC/Poison” for storing ECC codes and/or a poison bit or poison code, as further described below. DB 414 and a register clock driver (RCD) circuit (not shown) generally provide a memory channel interface circuit for coupling to memory controller 420 over memory bus 415.

While in this implementation, metadata processing circuit for poison data is shown embodied in the DRAM chips, in other implementations similar functionality may instead be embodied in data buffer 414 for each DRAM chip.

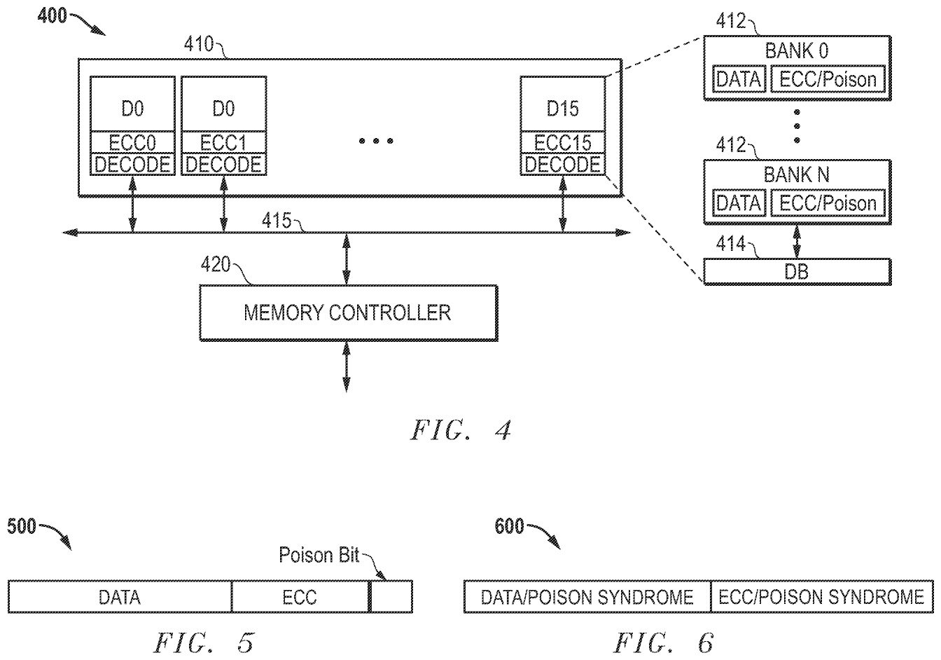

FIG. 5 illustrates in diagram form a set of data 500 stored in a memory according to some embodiments. Generally, the depicted set of data 500 represents a row of memory holding a number of cache lines, such as 32-byte cache lines or 64-byte cache lines, and is stored in designated addresses in one or more DRAM chips of a GDDR module such as memory module 400. In this implementation, the DRAM chip includes locations for storing the payload data, labelled “DATA”, locations for storing on-die ECC data associated with the payload data, labelled “ECC”, and bit location for storing a poison bit for the payload data labelled “Poison Bit”. In some implementations, ECC data may not be used. Memory module 400 includes a dedicated bit for each set of data to hold the poison bit. In this implementation, the ECC code uses eighteen 8-bit symbols to make a 144-bit ECC word made up of 128 data bits and 16 check bits. This ECC code is a single symbol correcting code which can detect 93.7% of bit error combinations for double symbol errors. Preferably, the poison flag bit is part of the data payload and is therefore protected by the on-die ECC, protected in transit over the data lines of the memory bus by the link cyclic-redundancy check (CRC) checks.

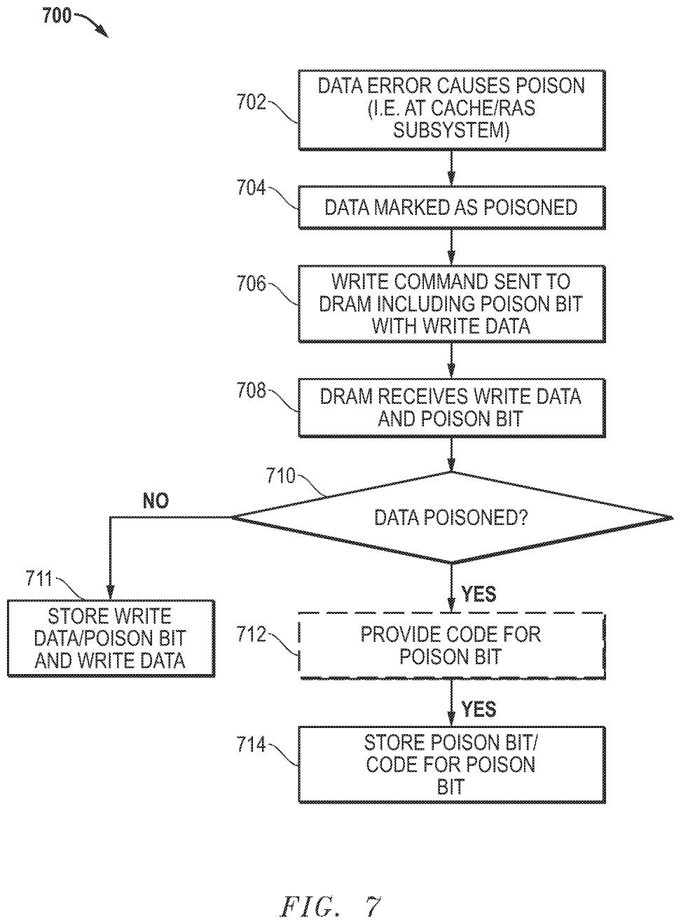

FIG. 6 illustrates in diagram form a set of data 600 stored in a memory according to some other embodiments. In the depicted implementation, rather than using a single bit to indicate that data is poisoned, a code or “syndrome” is stored indicating that the data is poisoned. Such a poison syndrome may be stored in place of an ECC code for the data, as indicated in the right in set of data 600 by the label “ECC/POISON SYNDROME”. In some implementations, at least part of the poison syndrome is stored in the memory locations for the data payload, as indicated on the left of the depicted set of data 600 by the label “DATA/POISON SYNDROME”. That is, the poison syndrome code includes a combination of a predetermined value stored in the ECC storage area and a predetermined value stored in place of the write data. This is allowed because when data is poisoned by the host system, the poised data payload itself does not need to be stored in some implementations.

FIG. 7 is a flow diagram 700 of a process for performing storing data poison information according to some embodiments. The depicted process is suitable for use with memory controller 320 (FIG. 3), or other suitable memory controllers that are able to receive poison data from a host system and interface with a memory to store such data.

The process begins at block 702 where a data error causes data to be recognized as poisoned. Such an error may be recognized by the system cache or elsewhere in the Reliability, Availability, and Serviceability (RAS) subsystem of the host processing system. Responsive to recognizing such an error, the data is marked as poised at block 704. Typically, the poisoning is marked on a cache line basis, but other marking processes may be used.

Some processes may need to store data to memory even though it has been poisoned. As shown at block 706, a write command is sent to a DRAM memory including a poison bit accompanying the write data. For embodiments using the storage scheme of FIG. 5, a single bit is transmitted with the data payload on the data (DQ) lines of the memory channel interface indicating the data is poisoned. Preferably the poison bit is transmitted in the metadata for a data payload. For embodiments using the storage scheme of FIG. 6, a poison syndrome generation circuit (i.e., 327, FIG. 3) generates a poison syndrome code value for an ECC code, which is transmitted with the data on the DQ lines of the memory channel interface. The DRAM memory receives the write command over the command interface of the memory bus, and the write data and poison information over the DQ lines, as shown at block 708.

At block 710, the process at the DRAM memory interprets the poison bit. If the data is poisoned the process may go to block 714 where it stores the poison bit, or it may first generate a code for storage indicating the data is poisoned as shown at optional block 712. For example, a particular ECC syndrome (FIG. 6) may be used as a poison syndrome to indicate that the data is poisoned. In some implementations, a poison syndrome is created by the memory controller, while in other implementations a poison syndrome is created at the DRAM memory. For example, a metadata processing circuit may be implemented in the data buffer chips (i.e. 414, FIG. 4) of the DRAM, or in the DRAM chips, for receiving the poison bit, interpreting it, and creating a poison syndrome to indicate when data is poisoned.

At block 714, either the poison bit or the poison syndrome or code is stored in the DRAM memory. Because poisoned data is not required to be read, some implementations do not save the poisoned data itself at block 714, while some do.

At block 711, responsive to the poison bit indicating that the write data is not poisoned, the process includes storing the write data in a selected memory bank and not storing a code indicating the value of the poison bit. In some implementations, the poison bit is stored with a value indicating the data is not poisoned, for example a “0” value, while in other implementations the absence of a poison syndrome code value in the ECC is used to indicate that the data is not poisoned, and no separate data is stored to indicate that the data is not poisoned.

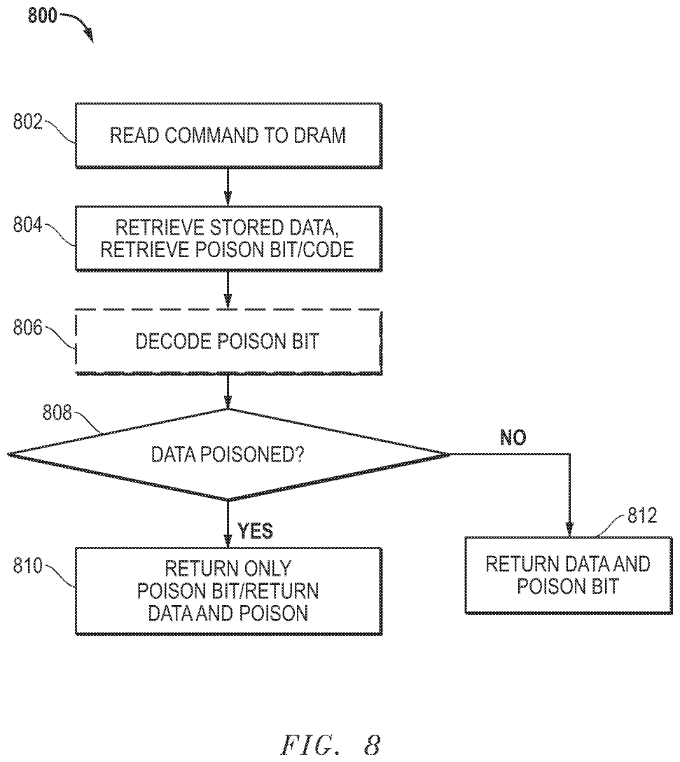

FIG. 8 is a flow diagram 800 of a process for reading data from a DRAM memory including a poison indication according to some embodiments. The process is suitable for use with memory controller 320 (FIG. 3), or other suitable memory controllers that are able to store data with a poison indication as described with respect to FIG. 7.

At block 802, a read command is sent to the DRAM memory from the memory controller. At block 804, when the read command is implemented at the DRAM memory, the process retrieves any stored data and the poison bit or poison syndrome code from DRAM. If a poison syndrome code is used, the poison syndrome code is decoded or recognized at block 806.

At block 808, the process determines whether the data is poisoned. In various implementations, this determination may be made at the DRAM chip or on a data buffer chip on the DRAM memory. If the data is poisoned, the process goes to block 810 where it can, in various implementations, reproduce the poison bit and then return the poison bit only along with “dummy” data (which is typically selected to reduce power in data transmission), or return the data and the poison bit. The poison bit can be transmitted back to the memory controller over the DQ lines of the data bus as part of the data payload, typically as a metadata bit.

In other implementations, the DRAM memory itself does not make any determination and instead merely returns the data and proceeds to block 810 or block 812. The poison bit can be transmitted as an ECC syndrome which is interpreted at the memory controller.

If the data is not poisoned at block 808, the process goes to block 812 where it transmits the data and the poison bit back to the memory controller.

Various techniques for communicating, encoding/decoding, and storing poison information within a DDR memory protocol have been disclosed. The disclosed techniques allow the host memory system to track and store data poison indicators within the DDR memory protocol, without the host system memory controller separately storing poison data to additional memory addresses. The techniques enable data poison tracking in a manner generally transparent to the host system, without adding significant overhead to the DDR protocol. Further, the techniques herein allow flexibility for DRAM vendors in implementing the data poison indicator storage at the DRAM, allowing for storage of a poison bit, a code, or a poison syndrome storage in various implementations.

Memory controller 320 of FIG. 3 and memory module 400 of FIG. 4, or any portions thereof, may be described or represented by a computer accessible data structure in the form of a database or other data structure which can be read by a program and used, directly or indirectly, to fabricate integrated circuits. For example, this data structure may be a behavioral-level description or register-transfer level (RTL) description of the hardware functionality in a high level design language (HDL) such as Verilog or VHDL. The description may be read by a synthesis tool which may synthesize the description to produce a netlist including a list of gates from a synthesis library. The netlist includes a set of gates that also represent the functionality of the hardware including integrated circuits. The netlist may then be placed and routed to produce a data set describing geometric shapes to be applied to masks. The masks may then be used in various semiconductor fabrication steps to produce the integrated circuits. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, memory controller 320 may interface to other types of memory besides DDRx, such as high bandwidth memory (HBM), RAMbus DRAM (RDRAM), and the like. Still other embodiments may include other types of DRAM modules or DRAMs not contained in a particular module, such as DRAMs mounted to the host motherboard. Accordingly, it is intended by the appended claims to cover all modifications of the disclosed embodiments that fall within the scope of the disclosed embodiments.

What is claimed is:

1. A random-access memory (RAM) comprising:
a plurality of memory banks;
a memory channel interface circuit for coupling to a memory channel adapted for coupling to a memory controller; and
a metadata processing circuit coupled to the memory channel interface circuit and receiving a poison bit sent over the memory channel associated with a write command and write data for the write command,
wherein the RAM, responsive to the poison bit indicating that the write data is poisoned, stores at least one of: the poison bit and a code indicating a value of the poison bit in a selected memory bank.

2. The RAM of claim 1, wherein the RAM stores the poison bit in a designated location associated with the write data and, responsive to a read command for the write data, transmits the poison bit to the memory controller over the memory channel.

3. The RAM of claim 1, wherein the RAM, responsive to the poison bit indicating that the write data is poisoned, stores a code indicating the value of the poison bit at least partially in an error correction coding (ECC) storage area associated with the write data and, responsive to a read command for the write data, recognizes the code, reproduces the value of the poison bit based on the code, and transmits the poison bit to the memory controller over the memory channel.

4. The RAM of claim 3, wherein the RAM, responsive to the poison bit indicating that the write data is not poisoned, stores the write data in a selected memory bank and does not store a code indicating the value of the poison bit.

5. The RAM of claim 3, wherein the code includes a combination of a predetermined value stored in the ECC storage area and a predetermined value stored in place of the write data.

6. The RAM of claim 1, wherein the RAM, responsive to the poison bit indicating that the write data is poisoned, does not transmit the write data to the memory controller responsive to a read command for the write data.

7. A method, comprising:
at a random-access memory (RAM), and receiving a poison bit sent over a memory channel associated with a write command and write data for the write command;
at the RAM, responsive to the poison bit indicating that the write data is poisoned, storing at least one of: the poison bit and a code indicating a value of the poison bit in a selected memory bank of the RAM; and
responsive to a read command for the write data, transmitting the poison bit to a memory controller.

8. The method of claim 7, further comprising storing the poison bit in a designated location associated with the write data.

9. The method of claim 7, further comprising:
storing the code indicating the value of the poison bit at least partially in an error correction coding (ECC) storage area associated with the write data; and
responsive to a read command for the write data, recognizing the code and reproducing the value of the poison bit based on the code.

10. The method of claim 9, further comprising, responsive to the poison bit indicating that the write data is not poisoned, storing the write data in a selected memory bank and not storing a code indicating the value of the poison bit.

11. The method of claim 9, wherein the code includes a combination of a predetermined value stored in the ECC storage area and a predetermined value stored in place of the write data.

12. The method of claim 7, wherein the RAM, responsive to the poison bit indicating that the write data is poisoned, does not transmit the write data to the memory controller responsive to a read command for the write data.

13. A data processing system, comprising:
a data processor;
a data fabric coupled to the data processor; and
a memory controller coupled to the data fabric for fulfilling memory requests from the data processor;
a random access memory (RAM) coupled to the memory controller over a memory channel and comprising:
a plurality of memory banks;
a memory channel interface circuit for coupling to a memory channel adapted for coupling to a memory controller; and
a metadata processing circuit coupled to the memory channel interface circuit and receiving a poison bit sent over the memory channel associated with a write command and write data for the write command,
wherein the RAM, responsive to the poison bit indicating that the write data is poisoned, stores at least one of: the poison bit and a code indicating a value of the poison bit in a selected memory bank.

14. The data processing system of claim 13, wherein the RAM stores the poison bit in a designated location associated with the write data and, responsive to a read command for the write data, transmits the poison bit to the memory controller over the memory channel.

15. The data processing system of claim 13, wherein the RAM, responsive to the poison bit indicating that the write data is poisoned, stores a code indicating the value of the poison bit at least partially in an error correction coding (ECC) storage area associated with the write data and, responsive to a read command for the write data, recognizes the code, reproduces the value of the poison bit based on the code, and transmits the poison bit to the memory controller over the memory channel.

16. The data processing system of claim 15, wherein the RAM, responsive to the poison bit indicating that the write data is not poisoned, stores the write data in a selected memory bank and does not store a code indicating the value of the poison bit.

17. The data processing system of claim 15, wherein the code includes a combination of a predetermined value stored in the ECC storage area and a predetermined value stored in place of the write data.

18. The data processing system of claim 13, wherein the RAM, responsive to the poison bit indicating that the write data is poisoned, does not transmit the write data to the memory controller responsive to a read command for the write data.

19. The data processing system of claim 13, wherein the memory controller receives the poison bit from a caching system of the data processor.

20. The data processing system of claim 13, wherein the RAM includes a plurality of memory integrated circuit chips accessed with a data width of at least 32 bits.
